(19) United States
(12) Patent Application Publication
(10) Pub. No.: US 2022/0334380 A1
(43) Pub. Date: Oct. 20, 2022

(54) MIRROR-DRIVING MECHANISM AND OPTICAL MODULE

(71) Applicant: Sumitomo Electric Industries, Ltd., Osaka-shi, Osaka (JP)

(72) Inventor: Hiromi NAKANISHI, Osaka-shi, Osaka (JP)

(73) Assignee: Sumitomo Electric Industries, Ltd., Osaka-shi, Osaka (JP)

(21) Appl. No.: 17/635,382

(22) PCT Filed: Sep. 24, 2020
(86) PCT No.: PCT/JP2020/036053

§ 371 Date: Feb. 15, 2022

(30) Foreign Application Priority Data
Oct. 9, 2019 (JP) 2019-185683

(51) Int. Cl. G02B 26/10; G02B 5/08

(52) U.S. Cl. CPC G02B 26/105; G02B 5/0808

(57) ABSTRACT

A mirror-driving mechanism includes a stage having a recessed portion, a base portion in a plate shape, a mirror in a plate shape having a reflection surface configured to reflect light, and a photo detector having a photo detecting surface configured to receive light. The base portion has a through-hole and is disposed so as to cover an opening in the recessed portion. The mirror is disposed so as to be swingable in the through-hole away from a wall surface defining the through-hole. The photo detector is disposed in the recessed portion so as to overlap a region in which the through-hole is located when viewed in a thickness direction of the base portion.

### TECHNICAL FIELD

The present disclosure relates to a mirror-driving mechanism and an optical module.

The present application claims priority to Japanese Patent Application No. 2019-185683 filed on Oct. 9, 2019, the entire contents of which are hereby incorporated by reference.

### BACKGROUND ART

A known optical module includes a light-emitting portion that multiplexes light having multiple wavelengths from multiple semiconductor light-emitting elements and a scanning portion that scans the light from the light-emitting portion (see, for example, PTL 1 to PTL 3). Such optical module can draw a character or a figure by scanning the light from the light-emitting portion along a desired path.

### CITATION LIST

### Patent Literature

PTL 1: Japanese Unexamined Patent Application Publication No. 2014-186068
PTL 2: Japanese Unexamined Patent Application Publication No. 2014-56199
PTL 3: International Publication No. 2007/120831

### SUMMARY OF INVENTION

A mirror-driving mechanism according to the present disclosure includes a stage having a recessed portion, a base portion in a plate shape, a mirror in a plate shape having a reflection surface configured to reflect light, and a photo detector having a photo detecting surface configured to receive light. The base portion has a through-hole and is disposed so as to cover an opening in the recessed portion. The mirror is disposed so as to be swingable in the through-hole away from a wall surface defining the through-hole. The photo detector is disposed in the recessed portion so as to overlap a region in which the through-hole is located when viewed in a thickness direction of the base portion.

### BRIEF DESCRIPTION OF DRAWINGS

FIG. 1 is a schematic plan view of a mirror-driving mechanism included in an optical module according to Embodiment 1.

FIG. 2 is a schematic plan view of the optical module including the mirror-driving mechanism illustrated in FIG. 1.

FIG. 3 is a schematic sectional view of the mirror-driving mechanism included in the optical module illustrated in FIG. 2 taken along line III-III illustrated in FIG. 2.

FIG. 4 is a schematic plan view of a photo detector included in the mirror-driving mechanism according to Embodiment 1.

FIG. 5 is a schematic plan view of a photo detector included in a mirror-driving mechanism according to Embodiment 2.

FIG. 6 is a schematic plan view of a photo detector included in a mirror-driving mechanism according to Embodiment 3.

FIG. 7 is a schematic plan view of photo detectors included in a mirror-driving mechanism according to Embodiment 4.

FIG. 8 is a schematic plan view of a photo detector included in a mirror-driving mechanism according to Embodiment 5.

FIG. 9 is a schematic sectional view of an optical module including a mirror-driving mechanism according to Embodiment 6.

### DESCRIPTION OF EMBODIMENTS

### Problems to be Solved by Present Disclosure

In some cases where light from a light-emitting portion is scanned along a desired path, reflection from a mirror configured to be swingable is used. In order to scan the light from the light-emitting portion with precision, it is necessary to dispose the mirror at an appropriate position with precision with respect to the optical axis of the light emitted from the light-emitting portion. In order to efficiently manufacture an optical module, it is preferable to readily dispose the mirror at the appropriate position with precision.

In view of this, it is an object of the present disclosure to provide a mirror-driving mechanism and an optical module that make it easy to dispose a mirror at an appropriate position with precision with respect to the optical axis of light emitted from a light-emitting portion.

### Advantageous Effects of Present Disclosure

The mirror-driving mechanism described above makes it easy to dispose the mirror at the appropriate position with precision with respect to the optical axis of the light emitted from the light-emitting portion.

### Description of Embodiments of Present Disclosure

Aspects of the present disclosure will be first listed and described. A mirror-driving mechanism according to the present disclosure includes a stage having a recessed portion, a base portion in a plate shape, a mirror in a plate shape having a reflection surface configured to reflect light, and a photo detector having a photo detecting surface configured to receive light. The base portion has a through-hole and is disposed so as to cover an opening in the recessed portion. The mirror is disposed so as to be swingable in the through-hole away from a wall surface defining the through-hole. The photo detector is disposed in the recessed portion so as to overlap a region in which the through-hole is located when viewed in a thickness direction of the base portion.

As for the mirror-driving mechanism according to the present disclosure, the mirror disposed so as to be swingable reflects light emitted from a light-emitting portion and scans the light emitted from the light-emitting portion. If the position of the mirror with respect to the optical axis of the light emitted from the light-emitting portion is inappropriate, the light emitted from the light-emitting portion cannot be appropriately scanned. As for the mirror-driving mechanism according to the present disclosure, the photo detector is disposed in the recessed portion so as to overlap a region in which the through-hole is located when viewed in the thickness direction of the base portion. If the position of the mirror with respect to the optical axis of the light emitted from the light-emitting portion is inappropriate, for example, the light emitted from the light-emitting portion passes through the through-hole, and the amount of light that reaches the photo detecting surface of the photo detector increases. Consequently, whether the mirror is disposed at the appropriate position with respect to the optical axis of the light emitted from the light-emitting portion can be grasped based on the amount of light received by the photo detector. Accordingly, at least the position of the light-emitting portion or the position of the mirror-driving mechanism with respect to the optical axis of the light emitted from the light-emitting portion is changed based on the amount of light received by the photo detector, and the position of the mirror can be adjusted to be the appropriate position. Consequently, the mirror-driving mechanism described above makes it easy to dispose the mirror at the appropriate position with precision with respect to the optical axis of the light emitted from the light-emitting portion.

The mirror-driving mechanism described above may include a plurality of the photo detectors. This makes it easier to grasp whether the mirror is disposed at the appropriate position, based on the amount of light received by the photo detectors and the arrangement of the photo detectors. Accordingly, it is easier to dispose the mirror at the appropriate position with precision with respect to the optical axis of the light emitted from the light-emitting portion.

As for the mirror-driving mechanism described above, the photo detecting surface may be divided into a plurality of regions. This enables whether the mirror is disposed at the appropriate position to be grasped based on the amount of light received in the divided regions of the photo detecting surface. Accordingly, it is easier to dispose the mirror at the appropriate position with precision with respect to the optical axis of the light emitted from the light-emitting portion.

As for the mirror-driving mechanism described above, the photo detector may be a position-detecting element. The position-detecting element is a sensor for detecting the position of spotted light by using the surface resistance of a photodiode and is not divided unlike, for example, a CCD (Charge-Coupled Device). Accordingly, the position-detecting element obtains a continuous electrical signal and has excellent position resolution and responsiveness. The use of the position-detecting element as the photo detector enables whether the mirror is disposed at the appropriate position to be grasped based on the amount of light received in each region of the photo detecting surface of the photo detector. Accordingly, it is easier to dispose the mirror at the appropriate position with precision with respect to the optical axis of the light emitted from the light-emitting portion.

As for the mirror-driving mechanism described above, a first imaginary plane being an imaginary plane containing an outer edge around the through-hole may tilt with respect to a second imaginary plane being an imaginary plane containing the photo detecting surface. This reduces a possibility that light reflected by the photo detecting surface of the photo detector exits from the mirror-driving mechanism to the outside and becomes stray light. Accordingly, the effect of the stray light on light emitted to the outside can be reduced.

An optical module according to the present disclosure includes a laser light source and the mirror-driving mechanism described above including the mirror configured to scan light emitted from the laser light source. The optical module makes it easy to dispose the mirror at the appropriate position with precision with respect to the optical axis of the light emitted from the light-emitting portion.

### DETAIL OF EMBODIMENTS OF PRESENT DISCLOSURE

An optical module including a mirror-driving mechanism according to an embodiment of the present disclosure will now be described with reference to the drawings. In the drawings described below, components like or corresponding to each other are designated by like reference signs, and a description thereof is not repeated.

### Embodiment 1

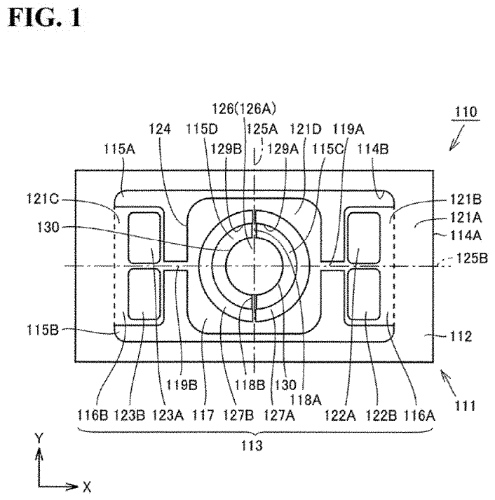

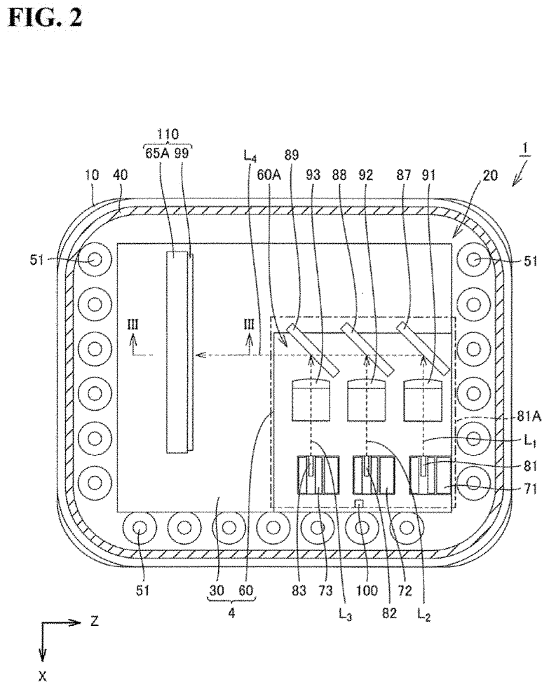

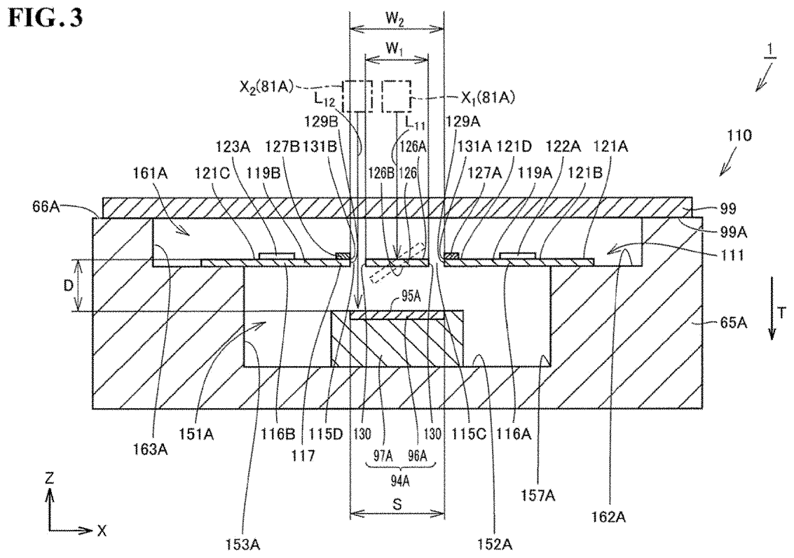

The structure of an optical module including a mirror-driving mechanism according to Embodiment 1 will now be described. FIG. 1 is a schematic plan view of the mirror-driving mechanism included in the optical module according to Embodiment 1. FIG. 2 is a schematic plan view of the optical module including the mirror-driving mechanism illustrated in FIG. 1. FIG. 3 is a schematic sectional view of the mirror-driving mechanism included in the optical module illustrated in FIG. 2 taken along line III-III illustrated in FIG. 2. FIG. 1 is viewed in the thickness direction of a base portion. The thickness direction of the base portion is illustrated by an arrow T in FIG. 3. In FIG. 2, a Z-direction represents a direction in which a red laser diode 81, a green laser diode 82, and a blue laser diode 83 described later are arranged. An X-direction represents a direction in which the red laser diode 81 emits light.

Referring to FIG. 1, FIG. 2, and FIG. 3, an optical module 1 includes a light-generating portion 20 that generates light and a foundation 10 and a cap 40 that surround the light-generating portion 20 and that have a plate shape. The foundation 10 includes multiple lead pins 51. The light-generating portion 20 is surrounded by the foundation 10 and the cap 40, and consequently, components included in the light-generating portion 20 are effectively protected from external environment.

The light-generating portion 20 includes a base member 4, the red laser diode 81 that emits red light in a direction illustrated by an arrow L₁, the green laser diode 82 that emits green light in a direction illustrated by an arrow L₂, the blue laser diode 83 that emits blue light in a direction illustrated by an arrow L₃, a first lens 91, a second lens 92, a third lens 93, a first filter 87, a second filter 88, and a third filter 89. The light emitted from the red laser diode 81, the light emitted from the green laser diode 82, and the light emitted from the blue laser diode 83 are multiplexed and emitted from the optical module 1 to the outside via a light exit window (not illustrated) formed in the cap 40. The base member 4 includes an electronic cooling module 30 and abase 60. The base 60 is joined to apart of the electronic cooling module 30. The temperatures of the red laser diode 81, the green laser diode 82, and the blue laser diode 83 are adjusted by using the Peltier effect of the electronic cooling module 30 with the base 60 interposed therebetween.

The base 60 has a plate shape. The base 60 has a main surface 60A having a rectangular shape (a square shape) when viewed in the thickness direction.

A first sub-mount 71, a second sub-mount 72, and a third sub-mount 73 each having a flat plate shape are arranged in the Z-direction on the main surface 60A of the base 60. The red laser diode 81 is disposed on the first sub-mount 71. The green laser diode 82 is disposed on the second sub-mount 72. The blue laser diode 83 is disposed on the third sub-mount 73. A thermistor 100 that detects the temperature of the base 60 is disposed on the main surface 60A of the base 60.

The first lens 91, the second lens 92, and the third lens 93 that convert the spot size of light are arranged in the Z-direction on the main surface 60A of the base 60. The first lens 91, the second lens 92, and the third lens 93 convert the spot sizes of the light emitted from the red laser diode 81, the green laser diode 82, and the blue laser diode 83. The first lens 91, the second lens 92, and the third lens 93 convert the light emitted from the red laser diode 81, the green laser diode 82, and the blue laser diode 83 into collimated light.

The first filter 87, the second filter 88, and the third filter 89 are arranged in the Z-direction on the main surface 60A of the base 60. The first filter 87 reflects the red light. The second filter 88 allows the red light to pass therethrough and reflects the green light. The third filter 89 allows the red light and the green light to pass therethrough and reflects the blue light. The first filter 87, the second filter 88, and the third filter 89 thus selectively allow light having a particular wavelength to pass therethrough or reflect light having a particular wavelength. Consequently, the first filter 87, the second filter 88, and the third filter 89 multiplex the light emitted from the red laser diode 81, the green laser diode 82, and the blue laser diode 83. The multiplexed light travels in a direction illustrated by an arrow L₄.

From the perspective of the ease of understanding, a structure surrounded by a one-dot chain line illustrated in FIG. 2 and including the red laser diode 81, the green laser diode 82, the blue laser diode 83, the first lens 91, the second lens 92, the third lens 93, the first filter 87, the second filter 88, and the third filter 89 is referred to as a laser light source 81A.

The optical module 1 includes the laser light source 81A and a mirror-driving mechanism 110 including a mirror 126 configured to scan the light emitted from the laser light source 81A. The mirror-driving mechanism 110 scans the light emitted from the laser light source 81A. The mirror-driving mechanism 110 includes a stage 65A having a first recessed portion 151A, a base portion Ill in a plate shape, the mirror 126 in a plate shape having a reflection surface configured to reflect light, a photo detector 94A having a photo detecting surface 95A configured to receive light, and a glass plate 99.

The structure of the base portion 111 and the mirror 126 will now be described.

According to the present embodiment, the mirror 126 has a circular plate shape. The diameter W₁ of a reflection surface 126A of the mirror 126 is, for example, 1.2 mm. For example, metal such as aluminum is deposited on the reflection surface 126A of the mirror 126. The mirror 126 is disposed such that the reflection surface 126A is along a surface 121A that corresponds to a main surface of the base portion 111.

Through-holes 115A, 115B, 115C, and 115D are formed in the base portion 111. That is, the base portion 111 has the through-holes 115A, 115B, 115C, and 115D. The mirror 126 is disposed in the through-holes 115C and 115D. The mirror 126 is disposed in the through-holes 115C and 115D away from inner wall surfaces 129A and 129B that are wall surfaces defining the through-holes 115C and 115D. The base portion 111 includes a driving portion 113 causing the mirror 126 to swing and a frame body 112 disposed so as to surround the driving portion 113. The base portion 111 includes a pair of first shafts 118A and 118B and a pair of second shafts 119A and 119B that serve as connectors connecting the inner wall surfaces 129A and 129B of the base portion 111 that surround the through-holes 115C and 115D and an outer edge 130 of the mirror 126. As illustrated in FIG. 1, the external form of the base portion 111 is a rectangular shape when viewed in the thickness direction of the base portion 111. The short sides of the base portion 111 extend in a Y-direction. The long sides of the base portion 111 extend in the X-direction. An outer wall surface 114A of the frame body 112 that corresponds to an outer wall surface of the base portion 111 has a pair of long sides and a pair of short sides when viewed in the thickness direction of the base portion 111. The frame body 112 has an annular shape. The driving portion 113 is disposed away from the outer wall surface 114A. The frame body 112 extends along the outer wall surface 114A. In a section in FIG. 3, a distance between the inner wall surface 129A and the inner wall surface 129B is illustrated by a width W₂.

The driving portion 113 includes a pair of first portions 116A and 116B and a second portion 117. In FIG. 1, the boundaries between the frame body 112 and the pair of first portions 116A and 116B are illustrated by dashed lines. The pair of first portions 116A and 116B is connected to the frame body 112. The first portions 116A and 116B extend toward each other from an inner wall surface 114B of the frame body 112. The second portion 117 has a rectangular shape when viewed in the thickness direction of the base portion 111. The surface 121A of the frame body 112, a surface 121B of the first portion 116A, and a surface 121C of the first portion 116B are formed so as to be continuous (see particularly FIG. 3).

The pair of second shafts 119A and 119B has a thin rod shape. The pair of second shafts 119A and 119B is connected to the pair of first portions 116A and 116B. The pair of second shafts 119A and 119B is connected to a part of an outer edge 124 of the second portion 117.

The second portion 117 has the through-holes 115C and 115D described above. The through-holes 115A and 115B are located between the second portion 117 and the pair of first portions 116A and 116B, between the second portion 117 and the frame body 112, and between the pair of first portions 116A and 116B and the frame body 112 except for a region in which the pair of second shafts 119A and 119B is located. The second portion 117 is supported by the pair of second shafts 119A and 119B with respect to the pair of first portions 116A and 116B and is swingable with the pair of second shafts 119A and 119B used as a swing axis. That is, the pair of second shafts 119A and 119B corresponds to a second support portion that supports the mirror 126 such that the mirror 126 is swingable.

The pair of first shafts 118A and 118B has a thin rod shape. The pair of first shafts 118A and 118B corresponds to a connector connecting the inner wall surfaces 129A and 129B of the base portion 111 that surround the through-holes 115C and 115D and the outer edge 130 of the mirror 126. The through-holes 115C and 115D are located between the second portion 117 and the mirror 126 except for a region in which the pair of first shafts 118A and 118B is located. The mirror 126 is supported by the pair of first shafts 118A and 1188 with respect to the driving portion 113 and is swingable due to resonance with the pair of first shafts 118A and 118B used as a swing axis. That is, the pair of first shafts 118A and 118B corresponds to a first support portion that supports the mirror 126 such that the mirror 126 is swingable. Portions at which the inner wall surfaces 129A and 129B and the surface 121A of the frame body 112 intersect correspond to outer edges 131A and 131B around the through-holes 115C and 115D.

The driving portion 113 includes a pair of piezoelectric elements 122A and 122B. The pair of piezoelectric elements 122A and 122B is disposed on the surface 1218 of the first portion 116A. The piezoelectric elements 122A and 122B are arranged away from each other in the Y-direction. The piezoelectric elements 122A and 122B have a rectangular shape when viewed in the thickness direction of the base portion 111. Similarly, the driving portion 113 includes a pair of piezoelectric elements 123A and 123B. The pair of piezoelectric elements 123A and 123B is disposed on the surface 121C of the first portion 116B. The piezoelectric elements 123A and 123B are arranged away from each other in the Y-direction. The piezoelectric elements 123A and 123B have a rectangular shape when viewed in the thickness direction of the base portion 111.

Voltages having opposite phases are alternately applied to the piezoelectric elements 122A and 1228, and voltages having opposite phases are alternately applied also to the piezoelectric elements 123A and 123B. This enables the second portion 117 to swing with respect to the first portions 116A and 116B with the pair of second shafts 119A and 1198 used as the swing axis. In this case, a second imaginary line 125B passing through the pair of second shafts 119A and 119B and illustrated by a one-dot chain line corresponds to the center axis of the swing. In this way, the second portion 117 can swing due to a piezoelectric phenomenon with the pair of second shafts 119A and 119B used as the swing axis. The swing of the second portion 117 causes the mirror 126 to swing. The second portion 117 swings at a frequency at which the second portion 117 does not resonate with the mirror 126. An optical swing angle of the swing of the second portion 117 is, for example, ±15°.

The driving portion 113 includes a pair of piezoelectric elements 127A and 127B. The piezoelectric elements 127A and 1278 are disposed on a surface 121D of the second portion 117. The piezoelectric element 127A is disposed along the inner wall surface 129A. The piezoelectric element 127B is disposed along the inner wall surface 129B.

Voltages having opposite phases are alternately applied to the piezoelectric elements 127A and 127B. This enables the mirror 126 to swing with respect to the second portion 117 with the pair of first shafts 118A and 118B used as the swing axis. In this case, a first imaginary line 125A passing through the pair of first shafts 118A and 118B and illustrated by a one-dot chain line corresponds to the center axis of the swing. In this way, the mirror 126 can swing due to the piezoelectric phenomenon with the pair of first shafts 118A and 118B used as the swing axis. The mirror 126 resonates. That is, the mirror 126 vibrates at the natural frequency thereof. This makes the mirror 126 easy to swing at a high speed. Also, this enables the optical swing angle of the swing of the mirror 126 to be increased. The optical swing angle is, for example, ±40°. In a plan view of the mirror-driving mechanism 110 illustrated in FIG. 1, the first imaginary line 125A and the second imaginary line 125B intersect at a right angle.

The structure of the stage 65A on which the base portion Ill is mounted will now be described. The stage 65A is joined to the electronic cooling module 30A at a position different from a position where the laser light source 81A is disposed. In particular, referring to FIG. 3, the stage 65A has a block shape. The stage 65A includes the first recessed portion 151A and a second recessed portion 161A. The second recessed portion 161A is defined by a second side wall surface 163A continuous with a first surface 66A of the stage 65A and a second bottom wall surface 162A continuous with the second side wall surface 163A. The second bottom wall surface 162A and the first surface 66A are parallel to each other. The stage 65A has the second bottom wall surface 162A that corresponds to a mount surface on which the base portion 111 is mounted. The base portion Ill is disposed so as to cover an opening in the first recessed portion 151A. The glass plate 99 is disposed such that a main surface 99A is in contact with the first surface 66A. The glass plate 99 seals the first recessed portion 151A and the second recessed portion 161A.

The first recessed portion 151A has a first bottom wall surface 152A away from the second bottom wall surface 162A in the Z-direction and has a first side wall surface 153A perpendicularly continuous with an outer edge 157A of the first bottom wall surface 152A. The first side wall surface 153A and the second bottom wall surface 162A that corresponds to the mount surface on which the base portion 111 is mounted are continuous with each other. The first bottom wall surface 152A is flat. The first side wall surface 153A extends in the Z-direction. The first side wall surface 153A is perpendicularly continuous with the first bottom wall surface 152A. The first bottom wall surface 152A is parallel to the surface 121A of the base portion 111. A distance between the surface 121A and the photo detecting surface 95A in the Z-direction is illustrated by a length D.

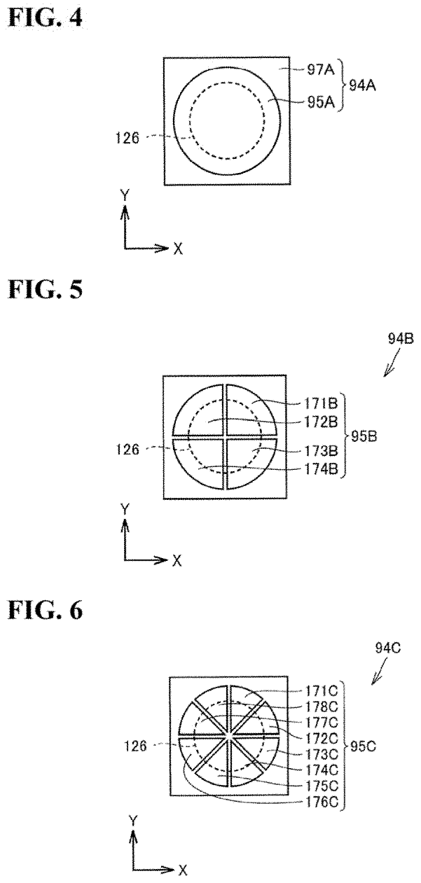

The photo detector 94A is mounted on the first bottom wall surface 152A. FIG. 4 is a schematic plan view of the photo detector 94A included in the mirror-driving mechanism 110 according to Embodiment 1. In FIG. 4, a position at which the refection surface 126A of the mirror is located is illustrated by a dashed line. Also, referring to FIG. 4, the photo detector 94A includes a light-receiving portion 96A that contains the photo detecting surface 95A and a support portion 97A that supports the light-receiving portion 96A. The photo detector 94A is disposed such that the photo detecting surface 95A is away from a back surface 126B of the mirror 126 so as to face the back surface 126B. The width S of the photo detecting surface 95A in the X-direction is greater than a width in the X-direction corresponding to the diameter W₁ of the mirror 126. According to the present embodiment, the width S of the photo detecting surface 95A in the X-direction is equal to the width W₂ that corresponds to the distance between inner wall surfaces 129A and 129B. The photo detector 94A is disposed so as to overlap a region in which the through-holes 115C and 115D are located when viewed in the thickness direction of the base portion 111. The photo detecting surface 95A is disposed so as to be visible from the through-holes 115C and 115D when viewed in the thickness direction of the base portion 111.

As for the mirror-driving mechanism 110 described above, the mirror 126 disposed so as to be swingable reflects the light emitted from the laser light source 81A corresponding to a light-emitting portion and scans the light emitted from the laser light source 81A. If the position of the mirror 126 with respect to the optical axis L₁₁ of the light emitted from the laser light source 81A is inappropriate, the light emitted from the laser light source 81A cannot be appropriately scanned. As for the mirror-driving mechanism 110 according to the present disclosure, the photo detector 94A is disposed in the first recessed portion 151A so as to overlap the region in which the through-holes 115C and 115D are located when viewed in the thickness direction of the base portion 111. If the position of the mirror 126 with respect to the optical axis of the light emitted from the laser light source is inappropriate, the light emitted from the laser light source passes through the through-holes 115C and 115D and reaches the photo detecting surface 95A of the photo detector 94A. Specifically, for example, in the case where the laser light source 81A is located at a position X₂, light on the optical axis L₁₂ of the light emitted from the laser light source 81A is not reflected by the mirror 126 but passes through the through-hole 115D and reaches the photo detecting surface 95A. Consequently, it can be grasped that the mirror 126 is not disposed at an appropriate position, based on the amount of light received by the photo detector 94A. Accordingly, at least the mirror-driving mechanism 110 or the laser light source 81A is moved based on the amount of light received by the photo detector 94A, and the position of the mirror 126 can be adjusted to be the appropriate position. According to the present embodiment, for example, the position of the laser light source 81A is changed from the position X₂ into a position X₁ in the X-direction. In the case where the laser light source 81A is located at the position X₁, the optical axis L₁₁ of the light emitted from the laser light source 81A passes through the center of the mirror 126. In this case, the mirror 126 is disposed at the appropriate position, and according to the present embodiment, the photo detector 94A does not receive the light from the laser light source 81A. That is, in this case, the amount of light received by the photo detector 94A is zero, and it can be grasped that the mirror 126 is disposed at the appropriate position, based on the amount of light received. The mirror-driving mechanism 110 described above makes it easy to dispose the mirror 126 at the appropriate position with precision with respect to the optical axis Lu of the light emitted from the laser light source 81A as described above.

The optical module 1 makes it easy to dispose the mirror 126 at the appropriate position with precision with respect to the optical axis of the light emitted from the laser light source.

According to the embodiment described above, the position of the mirror-driving mechanism 110 with respect to the laser light source may be changed such that the mirror is disposed at the appropriate position with precision. It goes without saying that both of the laser light source and the mirror-driving mechanism 110 may be moved.

### Embodiment 2

Embodiment 2 that is another embodiment will now be described. FIG. 5 is a schematic plan view of a photo detecting surface of a photo detector included in a mirror-driving mechanism according to Embodiment 2. The mirror-driving mechanism according to Embodiment 2 differs from that according to Embodiment 1 in that the structure of the photo detecting surface of the photo detector differs.

Referring to FIG. 5, a photo detector 94B included in the mirror-driving mechanism according to Embodiment 2 has a photo detecting surface 95B. The photo detecting surface 95B is divided into multiple light-receiving regions. Specifically, the photo detecting surface 95B is divided into a first light-receiving region 171B, a second light-receiving region 172B, a third light-receiving region 173B, and a fourth light-receiving region 174B. The first light-receiving region 171B, the second light-receiving region 172B, the third light-receiving region 173B, and the fourth light-receiving region 174B are arranged into an annular shape. This enables whether the mirror 126 is disposed at the appropriate position to be grasped based on the amount of light received in the light-receiving regions 171B, 172B, 173B, and 174B of the photo detecting surface 958 that is divided into the four regions. Accordingly, it is easier to dispose the mirror 126 at the appropriate position with precision with respect to the optical axis of the light emitted from the laser light source.

### Embodiment 3

Embodiment 3 that is another embodiment will now be described. FIG. 6 is a schematic plan view of a photo detector included in a mirror-driving mechanism according to Embodiment 3. The mirror-driving mechanism according to Embodiment 3 differs from those according to Embodiment 1 and Embodiment 2 in that the structure of a photo detecting surface of the photo detector differs.

Referring to FIG. 6, a photo detector 94C included in the mirror-driving mechanism according to Embodiment 3 has a photo detecting surface 95C. The photo detecting surface 95C is divided into multiple light-receiving regions. Specifically, the photo detecting surface 95C is divided into a first light-receiving region 171C, a second light-receiving region 172C, a third light-receiving region 173C, a fourth light-receiving region 174C, a fifth light-receiving region 175C, a sixth light-receiving region 176C, a seventh light-receiving region 177C, and an eighth light-receiving region 178C. The first light-receiving region 171C, the second light-receiving region 172C, the third light-receiving region 173C, the fourth light-receiving region 174C, the fifth light-receiving region 175C, the sixth light-receiving region 176C, the seventh light-receiving region 177C, and the eighth light-receiving region 178C are arranged into an annular shape. This enables whether the mirror 126 is disposed at the appropriate position to be grasped based on the amount of light received in the light-receiving regions 171C, 172C, 173C, 174C, 175C, 176C, 177C, and 178C of the photo detecting surface 95C that is divided into eight regions. According to the present embodiment, whether the mirror 126 is disposed at the appropriate position can be grasped with more precision than the mirror-driving mechanism according to Embodiment 2. Accordingly, it is easier to dispose the mirror 126 at the appropriate position with precision with respect to the optical axis of the light emitted from the laser light source.

### Embodiment 4

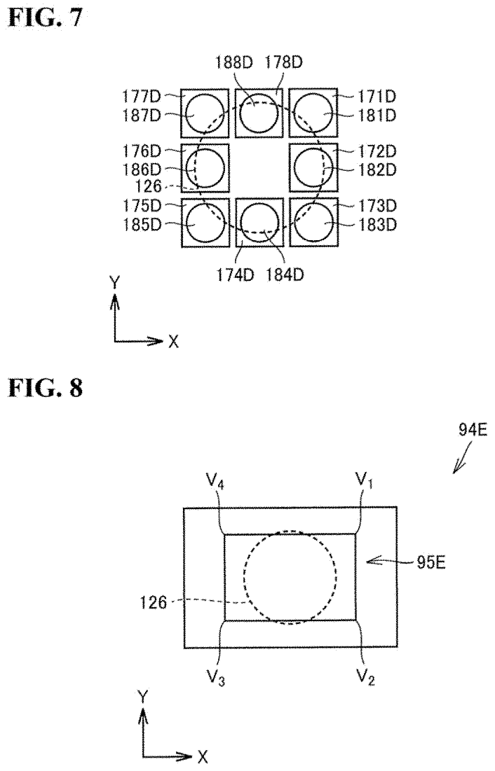

Embodiment 4 that is another embodiment will now be described. FIG. 7 is a schematic plan view of photo detectors included in a mirror-driving mechanism according to Embodiment 4. The mirror-driving mechanism according to Embodiment 4 differs from that according to Embodiment 1 in that the number of photo detectors differs.

Referring to FIG. 7, the mirror-driving mechanism according to Embodiment 4 includes multiple photo detectors. Specifically, the mirror-driving mechanism includes a first photo detector 171D having a first photo detecting surface 181D, a second photo detector 172D having a second photo detecting surface 182D, a third photo detector 173D having a third photo detecting surface 183D, a fourth photo detector 174D having a fourth photo detecting surface 184D, a fifth photo detector 175D having a fifth photo detecting surface 185D, a sixth photo detector 176D having a sixth photo detecting surface 186D, a seventh photo detector 177D having a seventh photo detecting surface 187D, and an eighth photo detector 178D having an eighth photo detecting surface 188D. The first photo detector 171D, the second photo detector 172D, the third photo detector 173D, the fourth photo detector 174D, the fifth photo detector 175D, the sixth photo detector 176D, the seventh photo detector 177D, and the eighth photo detector 178D are arranged in an annular shape. This enables whether the mirror 126 is disposed at the appropriate position to be grasped based on the amount of light received by the eight photo detectors 171D, 172D, 173D, 174D, 175D, 176D, 177D, and 178D. Accordingly, it is easier to dispose the mirror 126 at the appropriate position with precision with respect to the optical axis of the light emitted from the laser light source.

### Embodiment 5

Embodiment 5 that is another embodiment will now be described. FIG. 8 is a schematic plan view of a photo detector included in a mirror-driving mechanism according to Embodiment 5. The mirror-driving mechanism according to Embodiment 5 differs from that according to Embodiment 1 in that the structure of the photo detector differs.

Referring to FIG. 8, a photo detector 94E included in the mirror-driving mechanism according to Embodiment 5 and having a photo detecting surface 95E is a position-detecting element. The photo detecting surface 95E has a rectangular shape when viewed in the thickness direction of the base portion. The photo detector 94E can detect a region of the photo detecting surface 95E receiving light and a degree of the received light by detecting potentials V₁, V₂, V₃, and V₄ at four corners and deriving differences between the potentials at the four corners. The position-detecting element is a sensor for detecting the position of spotted light by using the surface resistance of a photodiode and is not divided unlike, for example, a CCD. Accordingly, the position-detecting element obtains a continuous electrical signal and has excellent position resolution and responsiveness. The use of the position-detecting element as the photo detector 94E enables whether the mirror 126 is disposed at the appropriate position to be grasped based on the amount of light received in each region of the photo detecting surface 95E of the photo detector 94E. Accordingly, it is easier to dispose the mirror 126 at the appropriate position with precision with respect to the optical axis of the light emitted from the light-emitting portion.

### Embodiment 6

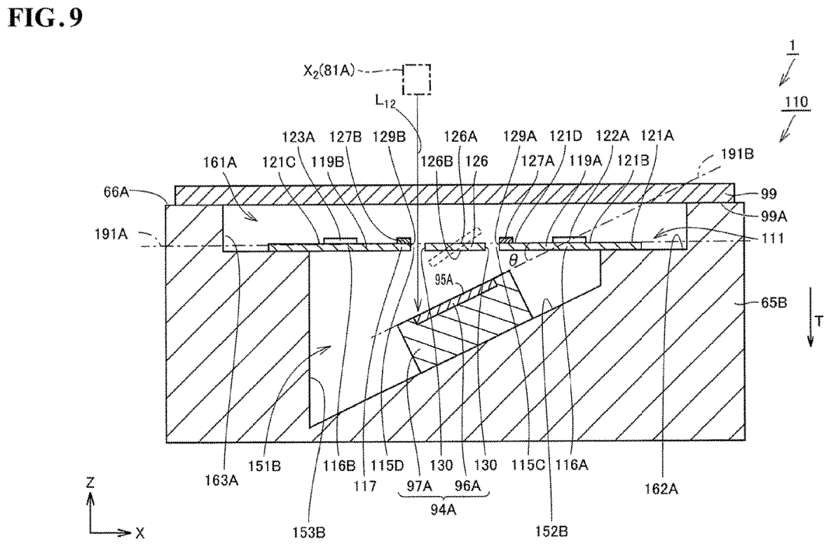

Embodiment 6 that is another embodiment will now be described. FIG. 9 is a schematic sectional view of an optical module including a mirror-driving mechanism according to Embodiment 6. The mirror-driving mechanism according to Embodiment 6 differs from that according to Embodiment 1 in that a photo detecting surface of a photo detector tilts.

Referring to FIG. 9, according to Embodiment 6, a second imaginary plane 191B being an imaginary plane containing the photo detecting surface 95A tilts with respect to a first imaginary plane 191A being an imaginary plane containing the outer edges 131A and 131B around the through-holes 115C and 115D. According to the present embodiment, a first bottom wall surface 152B that defines a first recessed portion 151B included in a stage 65B tilts with respect to the first imaginary plane 191A, and the second imaginary plane 191B consequently tilts with respect to the first imaginary plane 191A. An angle 9 formed between the first imaginary plane 191A and the second imaginary plane 191B is an acute angle. Consequently, in the case where the laser light source 81A is located at the position X₂, light emitted from the laser light source 81A and reflected by the photo detecting surface 95A of the photo detector 94A travels toward the other main surface of the base portion 111 and a first side wall surface 153B that defines the first recessed portion 151B and is reflected. Accordingly, a possibility that the light again passes through the through-holes 115C and 115D can be reduced. This reduces a possibility that the light reflected by the photo detecting surface 95A of the photo detector 94A exits from the mirror-driving mechanism 110 to the outside and becomes stray light. Accordingly, the effect of the stray light on light emitted to the outside can be reduced.

### Other Embodiments

According to the embodiments described above, the mirror swings due to the piezoelectric phenomenon but the configuration is not limited thereto. Another method, for example, electromagnetic force may be used to cause the mirror to swing.

According to the embodiments described above, the mirror-driving mechanism causes the mirror to swing by using the pair of first shafts and the pair of second shafts but the configuration is not limited thereto. The mirror-driving mechanism may cause the mirror to swing by using one of the pairs.

It is to be understood that the embodiments are disclosed herein by way of example in all aspects and are not restrictive in any aspect. The scope of the present disclosure is defined not by the above description but by the scope of claims and includes modifications having the same meaning and range as the scope of claims.

### REFERENCE SIGNS LIST

1 optical module
4 base member
10 foundation
60A, 99A main surface
20 light-generating portion
30 electronic cooling module
40 cap
51 lead pin
60 base
65A, 65B stage
66A, 121A, 121B, 121C, 121D surface
71 first sub-mount
72 second sub-mount
73 third sub-mount
81 red laser diode
81A laser light source
82 green laser diode
83 blue laser diode
87 first filter
88 second filter
89 third filter
91 first lens
92 second lens
93 third lens
94A, 94B, 94C, 94E, 171D, 172D, 173D, 174D, 175D, 176D, 177D, 178D photo detector
95A, 95B, 95C, 95D, 95E, 181D, 182D, 183D, 184D, 185D, 186D, 187D, 188D photo detecting surface
96A light-receiving portion
97A support portion
99 glass plate
100 thermistor
110 mirror-driving mechanism
111 base portion
112 frame toy
113 driving portion
114A outer wall surface
114B, 129A, 129B inner wall surface
115A, 115B, 115C, 115D through-hole
116A, 116B first portion
117 second portion
118A, 118B first shaft
119A, 119B second shaft
122A, 122B, 123A, 123B, 127A, 127B piezoelectric element
124, 130, 131A, 131B outer edge
125A, 125B imaginary line
126 mirror
126A reflection surface
126B back surface
151A, 151B first recessed portion
152A, 152B first bottom wall surface
153A, 153B first side wall surface
161A second recessed portion
162A second bottom wall surface
163A second side wall surface
171B, 172B, 173B, 174B, 171C, 172C, 173C, 174C, 175C, 176C, 177C, 178C light-receiving region
191A first imaginary plane
191B second imaginary plane
D length
L₁, L₂, L₃, L₄, T arrow
L₁₁, L₁₂ optical axis
S, W₁, W₂ width
V₁, V₂, V₃, V₄ potential
W₁ diameter
X₁, X₂ position

1. A mirror-driving mechanism comprising:
a stage having a recessed portion;
a base portion in a plate shape;
a mirror in a plate shape having a reflection surface configured to reflect light; and
a photo detector having a photo detecting surface configured to receive light,
wherein the base portion has a through-hole and is disposed so as to cover an opening in the recessed portion,
wherein the mirror is disposed so as to be swingable in the through-hole away from a wall surface defining the through-hole, and
wherein the photo detector is disposed in the recessed portion so as to overlap a region in which the through-hole is located when viewed in a thickness direction of the base portion.

2. The mirror-driving mechanism according to claim 1, wherein the mirror-driving mechanism includes a plurality of the photo detectors.

3. The mirror-driving mechanism according to claim 1, wherein the photo detecting surface is divided into a plurality of regions.

4. The mirror-driving mechanism according to claim 1, wherein the photo detector is a position-detecting element.

5. The mirror-driving mechanism according to claim 1, wherein a first imaginary plane being an imaginary plane containing an outer edge around the through-hole tilts with respect to a second imaginary plane being an imaginary plane containing the photo detecting surface.

6. (canceled)

7. The mirror-driving mechanism according to claim 2, wherein a first imaginary plane being an imaginary plane containing an outer edge around the through-hole tilts with respect to a second imaginary plane being an imaginary plane containing the photo detecting surface.

8. The mirror-driving mechanism according to claim 3, wherein a first imaginary plane being an imaginary plane containing an outer edge around the through-hole tilts with respect to a second imaginary plane being an imaginary plane containing the photo detecting surface.

9. The mirror-driving mechanism according to claim 4, wherein a first imaginary plane being an imaginary plane containing an outer edge around the through-hole tilts with respect to a second imaginary plane being an imaginary plane containing the photo detecting surface.

10. An optical module comprising:
a laser light source; and
a mirror-driving mechanism including a mirror configured to scan light emitted from the laser light source, the mirror-driving mechanism including
a stage having a recessed portion,
a base portion in a plate shape,
the mirror, the mirror having a plate shape having a reflection surface configured to reflect light, and
a photo detector having a photo detecting surface configured to receive light, wherein
the base portion has a through-hole and is disposed so as to cover an opening in the recessed portion,
the mirror is disposed so as to be swingable in the through-hole away from a wall surface defining the through-hole, and
the photo detector is disposed in the recessed portion so as to overlap a region in which the through-hole is located when viewed in a thickness direction of the base portion.

11. The optical module according to claim 10, wherein the mirror-driving mechanism includes a plurality of the photo detectors.

12. The optical module according to claim 10, wherein the photo detecting surface is divided into a plurality of regions.

13. The optical module according to claim 10, wherein the photo detector is a position-detecting element.

14. The optical module according to claim 10, wherein a first imaginary plane being an imaginary plane containing an outer edge around the through-hole tilts with respect to a second imaginary plane being an imaginary plane containing the photo detecting surface.

15. The optical module according to claim 11, wherein a first imaginary plane being an imaginary plane containing an outer edge around the through-hole tilts with respect to a second imaginary plane being an imaginary plane containing the photo detecting surface.

16. The optical module according to claim 12, wherein a first imaginary plane being an imaginary plane containing an outer edge around the through-hole tilts with respect to a second imaginary plane being an imaginary plane containing the photo detecting surface.

17. The optical module according to claim 13, wherein a first imaginary plane being an imaginary plane containing an outer edge around the through-hole tilts with respect to a second imaginary plane being an imaginary plane containing the photo detecting surface.
